(19) United States
(12) Patent Application Publication
(10) Pub. No.: US 2011/0084212 A1
(43) Pub. Date: Apr. 14, 2011

(54) Multi-layer photon counting electronic module

(75) Inventor: Stewart Clark, Newport Beach, CA (US)

(73) Assignee: Irvine Sensors Corporation, Costa Mesa, CA (US)

(21) Appl. No.: 12/924,141

(22) Filed: Sep. 20, 2010

Related U.S. Application Data
(60) Provisional application No. 61/277,360, filed on Sep. 22, 2009.

(51) Int. Cl. H01L 27/144

(52) U.S. Cl. 250/370.08; 250/208.1; 250/372

(57) ABSTRACT

A multilayer electronic module for photon counting such as in the solar blind region of the ultraviolet electromagnetic spectrum is provided.

The device comprises a photocathode for detecting photons and generating an electron output, a micro-channel plate for receiving the output electrons emitted from the photocathode in response to the photon input and amplifying same, readout circuitry and one or more bit-counting circuit layers used to count the electron output of the micro-channel plate.

### CROSS-REFERENCE TO RELATED APPLICATIONS

This application claims the benefit of U.S. Provisional Patent Application No. 61/277,360, filed on Sep. 22, 2009 and entitled “Three-Dimensional Multi-Level Logic Cascade Counter” pursuant to 35 USC 119, which application is incorporated fully herein by reference.

### STATEMENT REGARDING FEDERALLY SPONSORED RESEARCH AND DEVELOPMENT

Not applicable

### DESCRIPTION

1. Field of the Invention

The invention relates generally to the field of imaging technology. More specifically, the invention relates to a multi-layer, cascaded photon-counting electronic module with enhanced signal-to-noise ratio characteristics for use in the solar blind/ultraviolet electromagnetic spectrum.

2. Background of the Invention

Focal plane array technology used for solar blind imaging in the ultraviolet (UV) electromagnetic spectrum incorporating very small pixel detector sizes (i.e., about five microns) poses significant technical challenges. Challenges include those related to the integration of read-out integrated circuits (ROIC) for use in these mega-pixel sized arrays. Further, the goals of achieving a signal-to-noise ratio greater than ten, achieving a responsivity uniformity of better than 10% across mega-pixel arrays and providing a dynamic range of 60-80 db with frame rates on the order of kHz further constrain current FPA designs.

Small pixel sizes and large focal plane arrays are difficult to realize from both the electronic and detection aspects. However, ultraviolet imaging in the solar blind spectral region (i.e., in about the 200-290 nm region of the electromagnetic spectrum) provides the unique ability to capture target signatures in a very low background environment with high resolution.

In the UV spectral band, the majority of the UV radiation emitted by the Sun is absorbed by the Earth's ozone layer, making the background UV radiation near the Earth's surface close to zero. This beneficially results in significantly lower background UV radiation that negatively affects the signal-to-noise ratio of a detector device operating in that spectrum. In a low background environment such as the solar blind region, photon-counting imagers are beneficially used to provide a low noise, high dynamic range image and permit UV image detection in full daylight with little to no interference from the Sun.

Certain classes of photon counters desirably separate the photon conversion process from the electronics readout circuitry in such a way as to enable very small circuit geometries. This technology provides low-cost, high performance mega-pixel imagers for applications such as security/law enforcement. Other uses include military applications, e.g., multi-purpose imaging, missile threat warning, chemical and biological detection, etc.

The major technological challenges in the field of focal plane array technology are detector size, read out integrated circuit electronics size, detector materials, detector sensitivity/quantum efficiency, electronics noise, speed, and dynamic range; all of which are optimized by the electronic module disclosed herein. The disclosed invention mitigates the conflict between pixel size and available electronics real estate within the pixel boundaries by partitioning electronics into multiple layers in a three-dimensional stack of integrated circuit chips.

### SUMMARY OF THE INVENTION

By utilizing photon counters and micro-channel plate (MCP) technology in a three-dimensional electronic module, linearity, low noise, mega-pixel sized arrays and wide dynamic range are obtained. The use of the above elements in a novel, multi-layer electronic architecture enables photon counting for image generation that is both inherently linear and uniform.

The invention herein takes advantage of stacked electronic circuitry comprising a photocathode, a micro-channel plate and one or more bit counters to save space and increase performance while obtaining wide dynamic range in the photon counting process. The device preferably comprises twelve-bit counting circuitry cascaded over two or three layers in the stack.

In a first aspect of the invention, an electronic module comprising a stack of layers is provided comprising a photocathode layer for generating at least one electron in response to a photon arrival event, a micro-channel plate layer comprising at least one micro-channel for generating a cascaded electron output in response to the photon arrival event and a bit-counting circuit layer having a predetermined bit counting length for counting an electron output from a micro-channel.

In a second aspect of the invention, an electronic module is provided comprising a plurality of bit-counting circuit layers.

In yet a third aspect of the invention, an electronic module is provided wherein the photocathode layer is responsive to about the 200 nm to about the 290 nm wavelength of the electromagnetic spectrum.

In yet a fourth aspect of the invention, an electronic module is provided wherein the micro-channel plate is comprised of at least one micro-channel having a diameter of about less than 10 microns.

In yet a fifth aspect of the invention, an electronic module is provided wherein the micro-channel plate is comprised of at least one micro-channel having a diameter of about less than 5 microns.

In yet a sixth aspect of the invention, an electronic module is provided wherein at least one of the layers is in electrical connection with at least one of the other layers by means of at least one indium bump.

In yet a seventh aspect of the invention, an electronic module is provided wherein at least one of the bit-counting layers is comprised of a 4-bit counter.

In yet an eighth aspect of the invention, an electronic module is provided comprising circuitry for the processing of an image from the electron output of the micro-channel.

In yet a ninth aspect of the invention, an electronic module comprising a stack of layers is provided comprising a photocathode layer for generating at least one electron in response to a photon arrival event, a plurality of micro-channel plate layers each comprising at least one micro-channel for generating a cascaded electron output in response to the photon arrival event and at least one bit-counting circuit layer for counting an electron output from a micro-channel.

In yet a tenth aspect of the invention, an electronic module is provided comprising a photocathode layer for generating at least one electron in response to a photon arrival event, a plurality of micro-channel plate layers each comprising at least one micro-channel for generating a cascaded electron output in response to the photon arrival event and a plurality of bit-counting circuit layers for counting an electron output from a micro-channel.

While the claimed apparatus and method herein has or will be described for the sake of grammatical fluidity with functional explanations, it is to be understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112, are to be accorded full statutory equivalents under 35 USC 112.

### BRIEF DESCRIPTION OF THE DRAWINGS

FIG. 1 shows calculated flux as a function of altitude for a solar zenith angle of about thirty degrees.

FIG. 2 shows UV background measurements made at an altitude of 28.6 km at Fort Churchill, Manitoba, Canada.

FIG. 3 shows the variation of flux relative to the Earth's ozone layer.

FIG. 4 shows the probability of simultaneous photon arrivals over a 1e-9 second period.

FIG. 5 shows a preferred embodiment of the photon counting device of the invention.

FIG. 6 shows a sub-array multiplexing block diagram as a means of electronics partitioning the elements of the invention.

FIG. 7 shows a simplified depiction of the multi-layer photon counting electronic module.

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE INVENTION

Turning now to the figures wherein like numerals define like elements among the several views, a multi-layer photon-counter and cascaded bit-counter are provided which, in a preferred embodiment, operate in the ultraviolet electromagnetic spectrum.

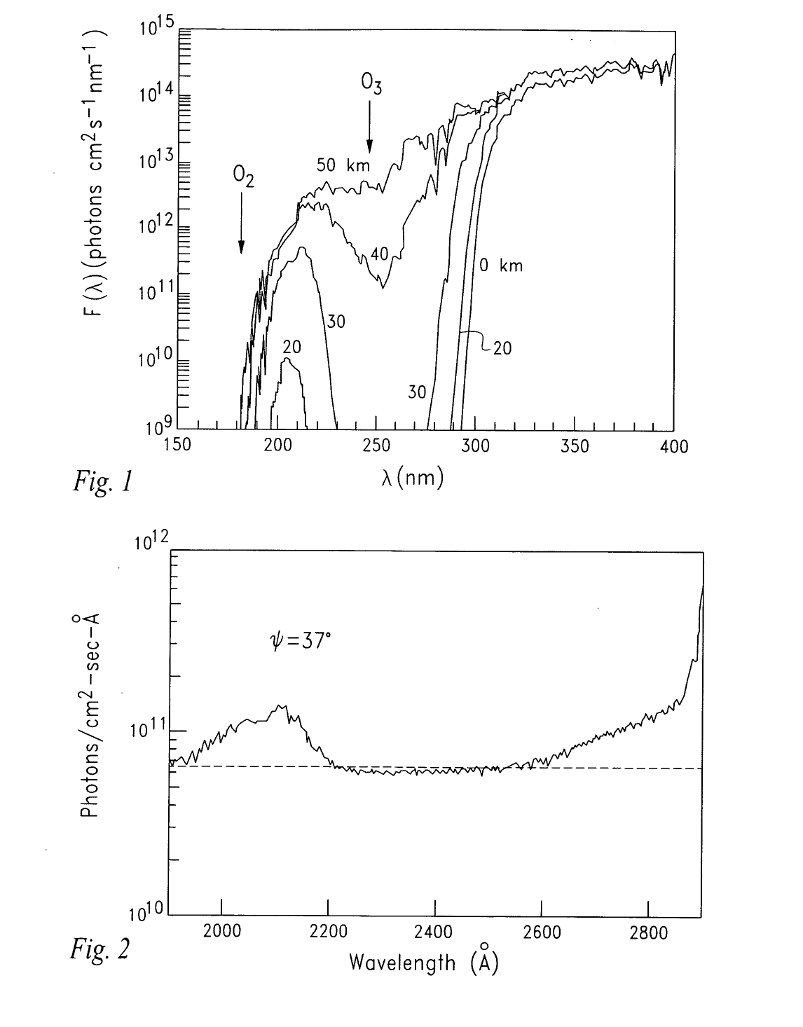

The wavelength of electromagnetic radiation in the solar blind region of the UV spectrum is about 0.200 to 0.290 microns, which is a desirably low background region. Near-Earth background flux is very low below 280 nm (˜1E11 from 200-280 nm) and does not increase until the altitude approaches the ozone layer. Integrated background photon flux is less than 1E11 ph/cm2/sec at ground level for a bandwidth of 200 to 280 nanometers. Measurements of this phenomenon are shown in the graph of FIG. 1.

Measurements made at 28.6 km at Fort Churchill, Manitoba, Canada (see FIG. 2) show that absorption of light with wavelengths between 2000 angstroms and 2800 angstroms typically vary only slightly, hovering at around 10E11 photons/cm²/sec/angstrom. This is near but just below the beginning of the ozone layer. Comparing the solar background near the ozone layer and the amount of background scattered light near the ozone layer disclose a challenge prior ultraviolet sensors may have with stray light control in maintaining low background; a problem addresses by the instant invention.

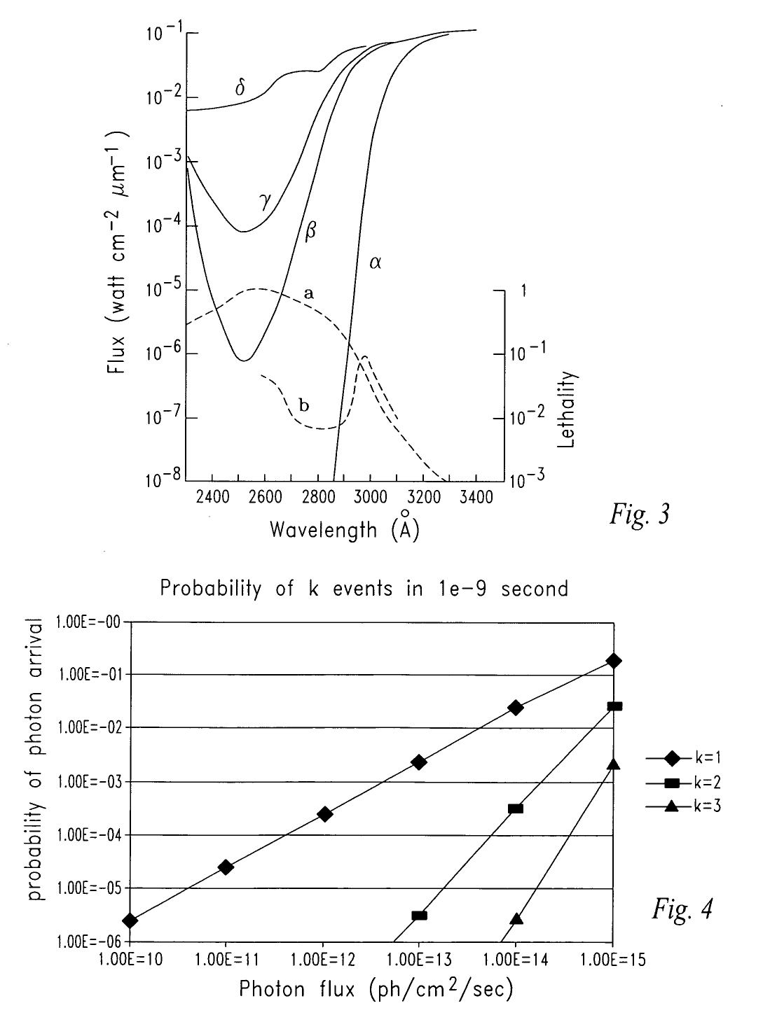

FIG. 3 depicts the effect of variations in ozone absorption, either with altitude (above 30 km) or with the ozone layer thickness: Curve α, after passing through a typical stratospheric ozone layer, Curve β, after passing through an O3 layer depleted to 10% of its present concentration, Curve γ, after passing through a layer depleted to 6% of the present O3 concentration, and Curve δ, flux at the top of the atmosphere. Curves a and b are unrelated to the invention (reproduced from Ruderman, 1974). (Copyright 1974 by the American Association for the Advancement of Science). Curve α gives Qb of better than 1E11, while is β is 1E13.

In the micro-channel plate photon counter of the invention, a single photon arrival event results in a large number of electrons (i.e., a cloud of electrons) that are detected with high confidence using a simple threshold discriminator. The size of the electron cloud does not indicate the intensity of the signal; it just makes the detection of a single photon easier. Intensity is indicated by the number of photons arriving in a given time period. To accurately estimate the size of a total photon flux, two processes must be considered; the event discriminator and the event counter.

For the event discriminator, there is a finite probability that two or more photons will fall on the micro-channel plate (or avalanche photodiode) during the single event time interval. This occurs when a single photon hits the micro-channel plate before the micro-channel plate has a chance to recharge its electric field. In this case, the event discriminator can undercount the photon flux since the electron cloud is not significantly different for the two photons. To estimate the probability of this occurrence, let the radiation of photons from the source with a constant optical power be a random process described by Poisson statistics; i.e., the equation:

P(k,T)=(nT)^{k}/(e^{-nT})

gives the probability that k photons will be registered in the time period T during one measurement where n is the average number of radiated photons per time unit, T is the width of the time interval in which the photons are detected and k is the number of registered photons. (See also FIG. 4).

To simplify the above model, it is assumed that the minimum pulse width for an event for a micro-channel plate is one nanosecond and that during this time, simultaneously arriving photons can be counted only as a single event. A photon arrival event generates a cloud of thousands of electrons. The total number of photon arrival events per time period determines intensity. Photons that are counted consist of both background photons and signal photons. Simultaneous arrivals during the high speed sampling interval result in under-counting the optical signal. For sample times of one nsec, the probability of multiple occurrences for photon fluxes that are less than 1E13 is very low.

The noise associated with the event counter because of the statistical nature of the photon flux is the square root of the counted flux, which is typically the model for conventional imagers.

The sample width that can be tolerated for various uniform photon rates is dependent upon pixel size in that smaller pixels tend to result in fewer photons per time period. In an exemplar five micron diameter micro-channel or pixel, a typical one nanosecond sample width would handle uniform photon rates of 4E15 ph/cm2/sec, but a thirty micron micro-channel with a one nanosecond pulse width can handle only 1E14 ph/cm2/sec at a uniform rate. Of course the photon arrival rate is not a uniform process and miscounting may underestimate the signal.

Another way of looking at the above concern is, assuming a background photon flux of 1E12 ph/cm2/sec and a five micron pixel, the event rate from the pixel is 2.5E5 photons/second or one event every 4096 msec (a full count of a 12-bit counter running at 1 GHz). An additional signal of 1E4 photons could be counted (˜1E16 ph/cm2/sec or 80 dB dynamic range).

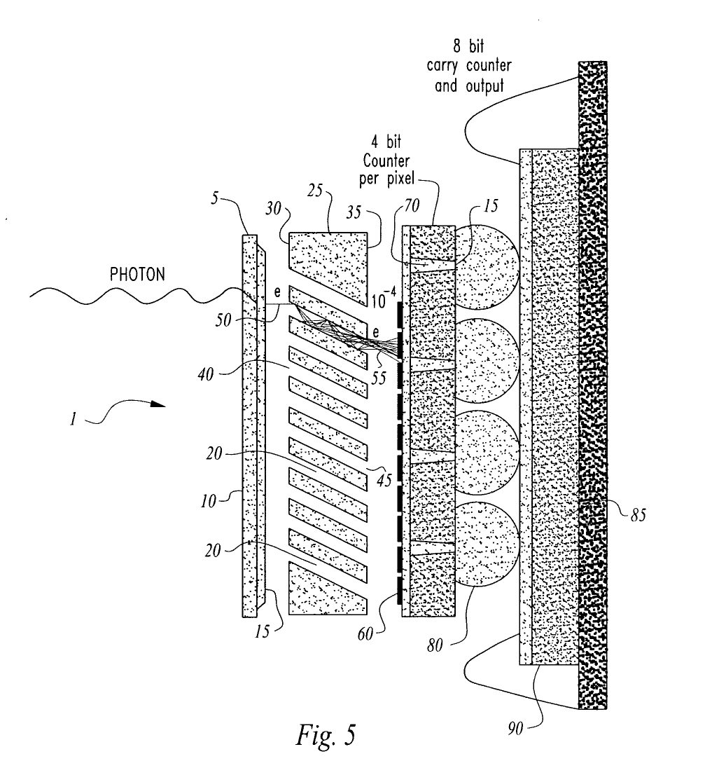

Turning now to the preferred embodiment of the invention shown in FIG. 5, photon counting and micro-channel plate (MCP) technology are integrated into a three-dimensional electronic module to provide a high-circuit density structure for use in electronic imaging.

Module 1 generally comprises a stack of layers comprising a photocathode 5 having a photocathode input surface 10 and a photocathode output surface 15.

Photocathode 5 converts input photons of a predetermined frequency from a scene of interest into output electrons which exit photocathode output surface 15 and are received by one or more micro-channels 20 disposed through the thickness of a micro-channel plate 25. In a preferred embodiment, photocathode 5 is responsive to about the 200 nm to about the 290 nm wavelength of the electromagnetic spectrum.

Photocathode 5 may comprise a negatively charged electrode designed to operate in the solar blind ultraviolet electromagnetic region. When struck by photons in the solar blind region, the photocathode emits one or more electrons due to the photoelectric effect, generating an electrical current flow through it. The micro-channels are arranged in a fashion such that they parallel to each other, and in preferred embodiments, are defined at a predetermined angle relative to the micro-channel input surface 30 and micro-channel output surface 35 of micro-channel plate 25.

As is known in the field of micro-channel plate technology, micro-channels 20 function as electron multipliers acting as pixels when under the presence of an electric field.

In operation, an electron emitted from photocathode 5 is admitted to the micro-channel input 40 of micro-channel 20. The orientation of micro-channel 20 assure the electron will strike a wall or walls of micro-channel 20 because of the angle at which the micro-channels are disposed with respect to planar surface of the micro-channel plate. The collision of an electron with the interior walls of micro-channel 20 causes an electron “cascading” effect; resulting in the propagation of a plurality of electrons through the micro-channel and toward micro-channel output surface 35.

The cascade of electrons exits micro-channel output 45 as an electron “cloud”, whereby the electron input signal 50 is amplified (i.e., cascaded) by several orders of magnitude to define an electron output signal 55.

Design factors affecting the amplification of the electron output signal 55 from micro-channel 20 include electric field strength, the geometry of the micro-channels and the micro-channel plate device material. Subsequent to the electron output signal 55 exiting micro-channel 20, the micro-channel recharges during a refresh period before another electron input signal 50 is detected as is known in the field of micro-channel plate technology.

Electron output signal 55 comprising a cascaded plurality of electrons from micro-channel 20 is received by an electrically conductive member 60 that is in electrical communication with suitable read out circuitry.

The electrical communication may be such as by electrically conductive vias 70 and backside contacts 75 in contact with suitable read out circuitry such as a read out integrated circuit (ROIC) for converting electron output signal 55 to a digitized signal and further comprising bit-counting circuitry, preferably using a four-bit counter per micro-channel.

Photocathode output surface 15 disposed proximal and coplanar with micro-channel input surface 30 whereby when a photon strikes photocathode input surface 10, an electron is emitted thereby and enters a micro-channel 20 disposed through the micro-channel plate, generating an electron cascade effect and defining a photon arrival event. The electrons generated by the photon arrival event are counted using the cascaded bit-counting elements of the stacked assembly and the micro-channel plate output is processed using suitable circuitry whereby an image is produced.

The photocathode and micro-channel plate of the invention are available from Hamamatsu or Photonis (Burle) and are preferably integrated with the ROIC. In one embodiment, the micro-channel plate may be optimized using atomic layer deposition (ALD) films for conductive, secondary electron emission, photocathode and stabilization layers to simplify integration.

The three-dimensional stacked microelectronic architecture of the invention permits considerably lower detector size.

In the preferred embodiment of the instant invention, at least two separate bit-counting layers are provided, i.e., first bit counting layer 85 and second bit-counting layer 90 are stacked on top of one another, both being in electrical communication with each other. The invention may comprise additional bit-counting layers beyond two layers depending on the end requirements of the user.

In a preferred embodiment, indium bumps 80 are used to as means for electrical communication between at least two of the stacked bit-counting elements.

Note that pixel size is typically set equal to or greater than the optics' diffractive blur which is 2.7 microns at a wavelength of 280 nm at f/4. Assuming a minimum pixel goal of five microns, diffraction is not a limitation. Another limiting factor in the prior art is the pixel-to-electronics interconnect and through-substrate vias. Because the pixels of the disclosed invention are integrated with the electronics and because the interconnects are not mechanical, five micron pixels are realizable. However, the photocathode should be in relatively close proximity and the micro-channel diameter size must be about 2-3 microns to achieve the five micron pixel size.

Selected photocathode detector materials depend on the spectral band of interest. Silicon is not desirable for solar blind UV detection, but acceptable materials include, but are not limited to nitrides, diamond, CsTe and CdTe. These materials are somewhat difficult to integrate directly on silicon chips.

Nitrides, CsTe, CdTe and diamond all demonstrate qualities sought after in photocathode detector materials suitable for use in the invention. Using photocathode detectors fabricated from these materials minimizes the need for optical filters to suppress the visible-NIR continuum and do not require cooling.

As discussed above, photon counting sensors determine the rate of an incoming photon stream by counting the arrival of each photon over a predetermined period of time. Each photon arrival results in a large electron cloud due to the micro-channel plate cascading effect. If the arrival rate is low enough or the detection process fast enough that multiple events do not merge into each other, the noise of this process can be as low as a single electron and dynamic range relatively large.

The invention herein takes advantage of electronics processing to obtain an 80-dB dynamic range, photon counting processing function in a five micron pixel size and is capable of being implemented in mega-pixel size arrays. Estimates of areas required for a 4-bit digital counter from vary, but typically dimensions are on the order of about a 13 micron cell at 0.18 micron fabrication technology down to a 7 micron cell at 0.065 micron technology.

A novel analog counting function referred to as 3D Multilevel Cascade Counter Elements (3DMLLCCE), may be implemented in an alternative preferred embodiment of the invention because the electron cloud per event is relatively large (e.g., 1E3 to 1E6 electrons). At each detected event, a small uniform size marker set of charges is injected into a small capacitor. After 16 events, a full threshold is generated and a marker transferred to the next stage where it is injected into the next of 16 level stages. Only 16 levels need be differentiated so the signal-to-noise ratio is high.

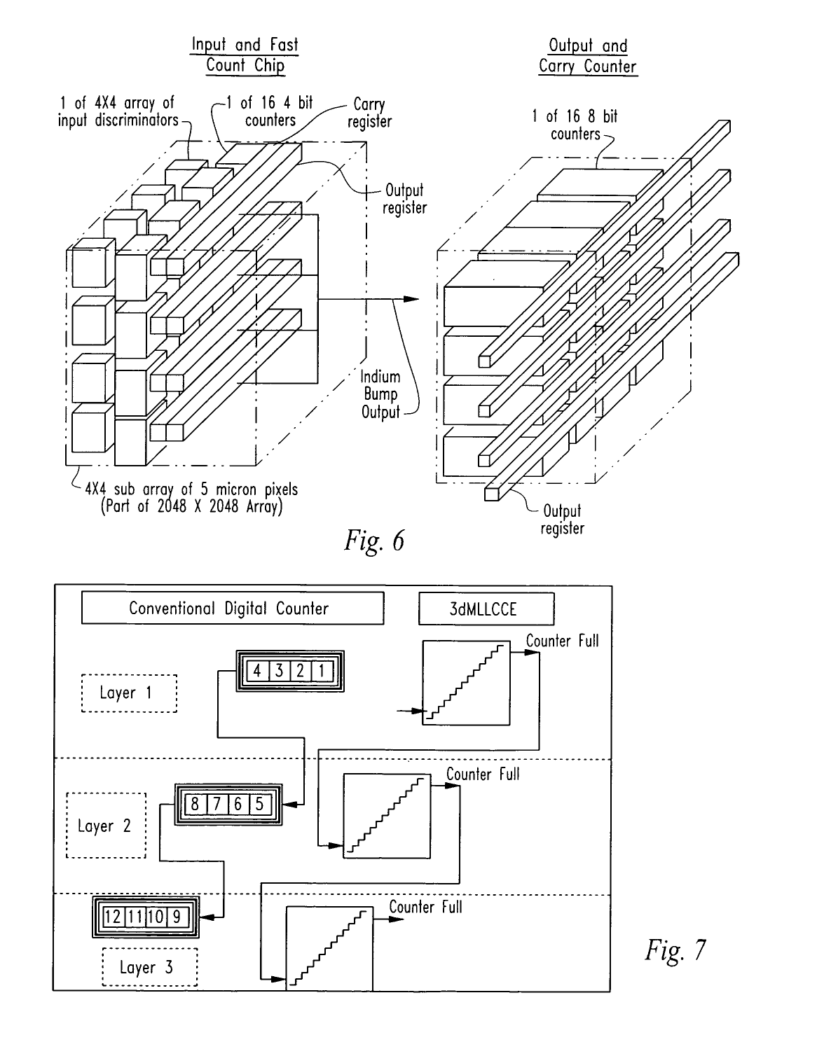

FIG. 6 shows an illustrative example of a preferred configuration of the invention. A 4-bit counter and 4×4 sub-array are used because electronics area estimates are close to a preferred pixel size of five microns. The sub-arrays are interconnected with an array of indium bumps on, for instance, a 20 micron pitch. A larger counter size allows for more relaxed bump pitch but requires higher density electronics. A smaller counter and sub-array require denser layer-to-layer interconnects.

FIG. 6 shows a block diagram of electronic layers composed of sub-arrays of 4×4 small pixels, each containing a 4-bit counter as a means for electronics partitioning.

For the digital counter, the carry results every 16 counts are transmitted to the adjacent layer. In a preferred embodiment, indium bumps are used as means for electrical communication. The transmission is serial at the clock rate because it occurs only once every 16 counts. The counter operates continuously with normal carry generation and resetting.

A separate buffer register is used to store and output results on the next count of 16 cycles. Counters on the second layer run a 1/16th the clock rate of the first layer. The architecture is flexible. For instance the structure may be three layers with a 4-bit counter in each layer, allowing identical chips.

As further embodiment is illustrated in FIG. 7, which has a detection front end that injects a small but relatively measured current into a storage element each time a photon arrival event occurs. This takes the place of a 4-bit digital counter. These injections increase the first layer step until full and a counter full bit is generated by a relatively tolerant threshold. The counter full bit is similar to a carry bit in a conventional counter and becomes the least significant bit count for the next layer. The counter full bit is the only information passed to the next layer during the count frame. For this application, three sets of 16 level 3DMLLCCE devices are used on each of three stacked chips to make a 12-bit 80 dB dynamic range counter.

Although the proposed design comprises 4-bit counters, it is to be understood that the proposed invention encompasses counters of varying bit capacities. The fact that 4-bit counters are utilized in this preferred embodiment is not to be taken as limiting in any way.

In the stack of layers, the least significant four bits are stored on layer 1, the middle four bits on layer 2, and the most significant four bits on layer 3. For a 64×64 pixel cell and a 4096 count at 1 GHz rate and a serial readout of “counter full” indicators, 4096 cells can be read out each count cycle per interconnect, however, data must be passed from element 1 on layer 1 to layer 2 every 16 counts (the minimum time to fill the first counter element). Therefore, 256 subframes are required for all 4096 pixels with each sub-frame requiring about 4.096 microseconds (a total of 1 msec per frame). Data is passed from layer 2 to layer 3 every 256 counts (minimum time to fill both 1 and 2). After 256 subframes of 4096 counts each, the elements are read out by monitoring the three 3DMLLCCE layers for full indication while counting down from 15 to 0 and inputting clearing values with each count. The value of each of the counter elements when a full is indicated represents the digital value of that 4-bit counter and the combination output as the pixel intensity.

This configuration uses small circuits and through-silicon-via (TSV) technology while maintaining one kHz rates and five micron pixels.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed in above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a sub-combination or variation of a sub-combination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptually equivalent, what can be obviously substituted and also what essentially incorporates the essential idea of the invention.

I claim:

1. an electronic module comprising a stack of layers wherein the layers comprise:
a photocathode layer for generating at least one electron in response to a photon arrival event,
a micro-channel plate layer comprising at least one micro-channel for generating a cascaded electron output in response to photon arrival event, and,
a bit-counting circuit layer having a predetermined bit counting length for counting an electron output from a micro-channel.

2. The electronic module of claim 1 comprising a plurality of the bit-counting circuit layers.

3. The electronic module of claim 1 wherein the photocathode layer is responsive to about the 200 nm to abut the 290 nm wavelength of the electromagnetic spectrum.

4. The electronic module of claim 1 wherein the micro-channel plate is comprised of at least one micro-channel having a diameter of about less than 10 microns.

5. The electronic module of claim 1 wherein the micro-channel plate is comprised of at least one micro-channel having a diameter of about less than 5 microns.

6. The electronic module of claim 1 wherein at least one of the layers is in electrical connection with at least one of the other layers by means of at least one indium bump.

7. The electronic module of claim 1 wherein at least on of the bit-counting layers is comprised of a 4-bit counter.

8. The electronic module of claim 1 further comprising circuitry for the processing of an image from the electron output of the micro-channel.

9. An electronic module comprising a stack of layers wherein the layers comprise:
a photocathode layer for generating at least one electron in response to a photon arrival event,
a plurality of micro-channel plate layers each comprising at least one micro-channel for generating a cascaded electron output in response to a photon arrival event, and,
a bit-counting circuit layer for counting an electron output from a micro-channel.

10. An electronic module comprising a stack of layers wherein the layers comprise:
a photocathode layer for generating at least one electron in response to a photon arrival event,
a plurality of micro-channel plate layers each comprising at least one micro-channel for generating a cascaded electron output in response to photon arrival event, and,
a plurality of bit-counting circuit layers for counting an electron output from a micro-channel.
